(19) United States
(12) Patent Application Publication
(10) Pub. No.: US 2003/0051814 A1
(43) Pub. Date: Mar. 20, 2003

(54) Manufacturing apparatus of a semiconductor device having a sensing system

(76) Inventor: Gi-Chung Kwon, Gyeonggi-do (KR)

Correspondence Address: LEWIS F. GOULD, JR.,, DUANE MORRIS LLP, ONE LIBERTY PLACE, PHILADELPHIA, PA, 19103, US

(21) Appl. No.: 10/246,254

(22) Filed: Sep. 17, 2002

(30) Foreign Application Priority Data
Sep. 18, 2001 (KR) 2001-57483

(51) Int. Cl. B05C 11/00; C23C 16/00; C23F 1/00

(52) U.S. Cl. 156/345.24; 118/713; 118/723 R; 118/733

(57) ABSTRACT

A manufacturing apparatus of a semiconductor device includes: a chamber having a sidewall; a window viewer of transparent material passing through the sidewall of the chamber; a window frame fixing the window viewer in the sidewall, the window frame having at least one opening; an image pickup device in the at least one opening, the image pickup device making image data showing a state of the chamber; and a logical operator connected to the image pickup device, the logical operator deciding whether the state of the chamber is normal or not by analyzing the image data.

This application claims the benefit of Korean Patent Application No. 2001-57483, filed on Sep. 18, 2001 in Korea, which is hereby incorporated by reference for all purposes as if fully set forth herein.

### BACKGROUND OF THE INVENTION

1. Field of the Invention

The present invention relates to a manufacturing apparatus of a semiconductor device and more particularly, to a sensing system.

2. Discussion of the Related Art

A development for a new material has been actively performed in the field and diverse large-scale integrated circuit (LSI) such as ultra large-scale integrated circuit (ULSI) has been developed due to a rapid growth of the new material development. That is, because the new material for forming thin films such as an insulating layer, a semiconductor layer and a conductor layer, which constitute a semiconductor device, has been developed widely in the field, the large-scale integrated circuit (LSI) such as the ultra large-scale integrated (ULSI) circuit is available now. The semiconductor devices are generally fabricated by repeated depositing and patterning process. These processes are accomplished in a manufacturing apparatus of the semiconductor device under vacuum condition.

The manufacturing apparatus of the semiconductor device is classified variously according to a purpose. The apparatus generally includes a processing chamber that is an airtight reaction container, a controller that controls surroundings within the chamber, and a gas supplying system that stores source gases and provides the source gases.

The semiconductor devices are generally fabricated by repeating processes of depositing and patterning. These processes are accomplished in a manufacturing apparatus of the semiconductor device under vacuum condition.

The manufacturing apparatus of the semiconductor device is variously classified according to a purpose. In general, the apparatus includes a processing chamber, a controller that controls surroundings within the chamber, and a gas supplying system that stores source materials and provides the source materials.

FIG. 1 shows a related art manufacturing apparatus of a semiconductor device, particularly for etching a thin film. In FIG. 1, the related art apparatus 10 includes a chamber 20 and a storage part 40 that stores and supplies a source material and a reaction material to the chamber 20.

The chamber 20 that is an airtight reaction container has an inlet 23 and an outlet 24, and a plate 26 is disposed in the chamber 10. The plate 26 divides the inside of the chamber 20 into two regions 28a and 28b. A plasma generation source 50 is arranged in a first region 28a and a chuck 30, which fixes a substrate 1 thereon, is placed in a second region 28b. The substrate 1 may include a thin film to be etched. The air in the chamber 10 is exhausted out of the chamber 10 through the outlet 24. After source and reaction materials of gas phase stored in the storage part 40 is injected into the chamber 20, the plasma generation source 50 generates a plasma in the second region 28b due to a variable electromagnetic field. The thin film of the substrate 1 on the chuck 30 is etched by using the plasma.

The plasma generation source 50 includes a first power source 52, a first impedance matching system 54 and an antenna 56. The first power source 52 supplies high frequency power such as radio frequency (RF) and the first impedance matching system 54 makes the impedance of a load equal to the internal impedance of the source of power, thereby making possible the most efficient transfer of power. The antenna 56 generates electric field with matched current as the load.

On the other hand, a bias source 60 is arranged in the chuck 30 and the bias source 60 controls impact energies of plasma ions, which are created by the plasma generation source 50. The bias source 60 includes a bias electrode 72, a second impedance matching system 74 and a second power source 76.

As stated above, the chamber 10 is an airtight reaction container, and thus the inside of the chamber 10 should be separated from the outside. The chamber 10, generally, is made of stainless steel or aluminum (Al), which is relatively low-priced and is opaque. Therefore, the process of dealing with the substrate cannot be observed from the outside.

Meanwhile, since high clean condition is required to minimize contamination of device being caused by impurities, the process is accomplished in a clean room that a user cannot go in and out easily. Accordingly, it is difficult to find that the apparatus is out of order before and after the process.

Specially, a plurality of apparatuses are now driven by a completely automated system in order to prevent devices from being contaminated and in order to improve productivity. Therefore, it is difficult that problems such as poor arrangement, deformation of the substrate due to temperature and the matter with the process are found while they are noticed easily at the early stage. The problems may be repeated, and cause a loss of materials and waste of expense.

### SUMMARY OF THE INVENTION

Accordingly, the present invention is directed to a manufacturing apparatus of a semiconductor device that substantially obviates one or more of problems due to limitations and disadvantages of the related art.

An advantage of the present invention is to provide a manufacturing apparatus of a semiconductor device that has a sensing system.

Another advantage of the present invention is to provide a manufacturing apparatus of a semiconductor device that the interior of the apparatus can be observed on the process.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a manufacturing apparatus of a semiconductor device includes: a chamber having a sidewall; a window viewer of transparent material passing through the sidewall of the chamber; a window frame fixing the window viewer in the sidewall, the window frame having at least one opening; an image pickup device in the at least one opening, the image pickup device making image data showing a state of the chamber; and a logical operator connected to the image pickup device, the logical operator deciding whether the state of the chamber is normal or not by analyzing the image data.

The window viewer includes a quartz. The window frame includes a bracket in the at least one opening and the bracket fixes the image pickup device. The bracket has a cylinder shape and is substantially normal to the sidewall. The image pickup device includes one of a charge coupled device (CCD) camera, a personal computer camera, an optical fiber scope and a wide viewing lens. The logic operator includes: a first conversion unit transforming the image data into manageable data; a control unit analyzing the manageable data; and an indicating unit showing analysis results of the control unit. The control unit compares the manageable data with reference data previously inputted. The control unit includes a data base, the reference data being saved in the data base. The indicating unit includes an image display device, a buzzer or a warning flare. The chamber includes: a plate dividing an interior of the chamber into first and second regions; a plasma generation source in the first region; and a chuck in the second region, the chuck having a bias source therein. The logic operator further includes: a second conversion unit connected to the plasma generation source; and a third conversion unit connected to the bias source. The second conversion unit transmits an off signal to the plasma generation source according to the analysis results. The third conversion unit transmits an off signal to the bias source according to the analysis results.

It is to be understood that both the foregoing general description and the following detailed description are exemplary and explanatory and are intended to provide further explanation of the invention as claimed.

### BRIEF DESCRIPTION OF THE DRAWING

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a schematic cross-sectional view of a related art apparatus of depositing a thin film;

FIG. 2 is a schematic cross-sectional view of an apparatus of depositing a thin film according to an exemplary embodiment of the present invention;

FIG. 3A is a schematic cross-sectional view of magnifying the part “A” of FIG. 2;

FIG. 3B is a view of showing a viewer frame; and

FIG. 4 is a view illustrating a logical operator.

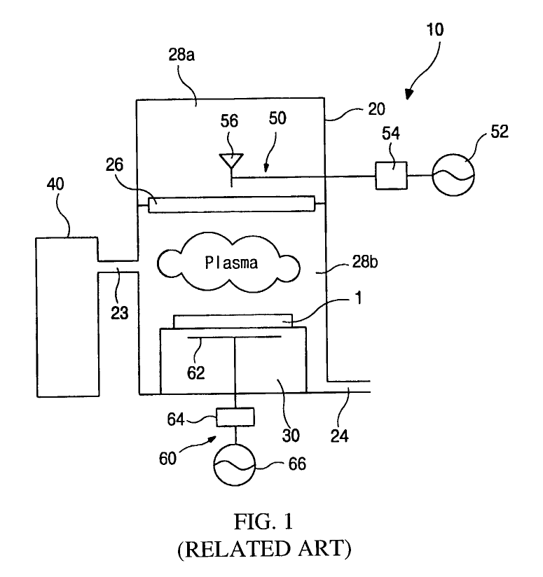

### DETAILED DESCRIPTION OF THE ILLUSTRATED EMBODIMENTS

Reference will now be made in detail to the illustrated embodiments of the present invention, which are illustrated in the accompanying drawings.

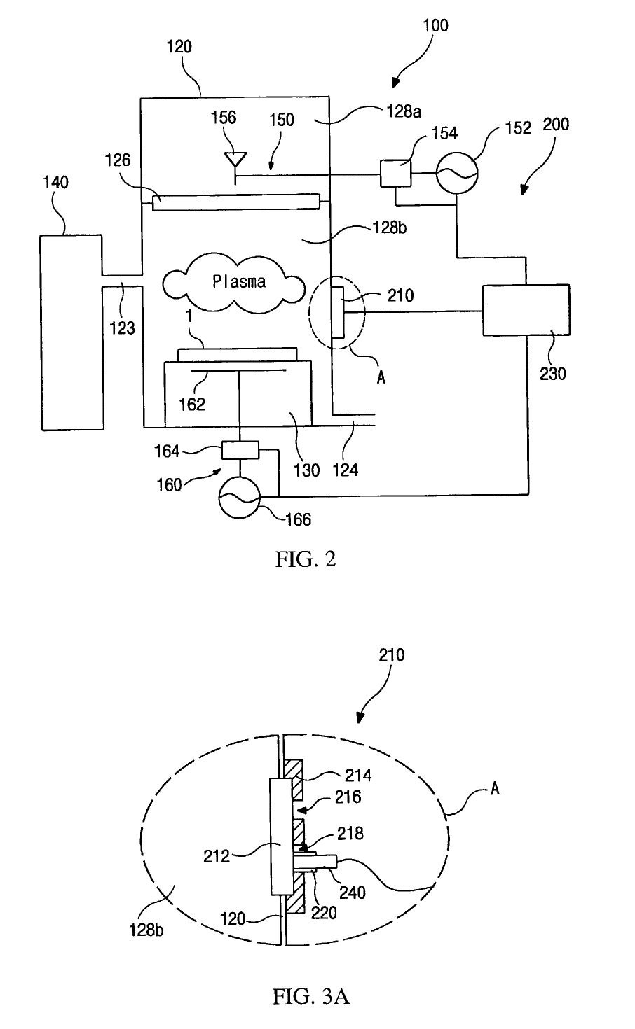

FIG. 2 shows a manufacturing apparatus of a semiconductor device, particularly for etching a thin film, according to the present invention. In FIG. 2, the apparatus 100 includes a chamber 120, in which processes are accomplished, and a storage part 140 that stores and supplies a source material and a reaction material to the chamber 120.

The chamber 120 that is an airtight reaction container has an inlet 123 and an outlet 124. Materials within the storage part 140 are supply to the chamber 100 through the inlet 124 and the air in the chamber 120 is exhausted out of the chamber 120 through the outlet 124. A plate 126 is disposed in the chamber 120 and divides the inside of the chamber 120 into two regions 128a and 128b.

A plasma generation source 150 is arranged in a first region 128a and a chuck 130, which fixes a substrate 1 thereon, is placed in a second region 128b. The substrate 1 may include a thin film to be etched. After source and reaction materials of gas phase stored in the storage part 140 is injected into the chamber 120, the plasma generation source 150 generates a plasma in the second region 128b due to a variable electromagnetic field. The thin film of the substrate 1 on the chuck 130 is etched by using the plasma.

The plasma generation source 150 includes a first power source 152, a first impedance matching system 154 and an antenna 156. The first power source 152 supplies high frequency power such as radio frequency (RF) and the first impedance matching system 154 makes the impedance of a load equal to the internal impedance of the source of power, thereby making possible the most efficient transfer of power. The antenna 156 generates electric field with matched current as the load.

On the other hand, a bias source 160 is arranged in the chuck 130 and the bias source 160 controls impact energies of plasma ions, which are created by the plasma generation source 150. The bias source 160 includes a bias electrode 162, a second impedance matching system 164 and a second power source 176.

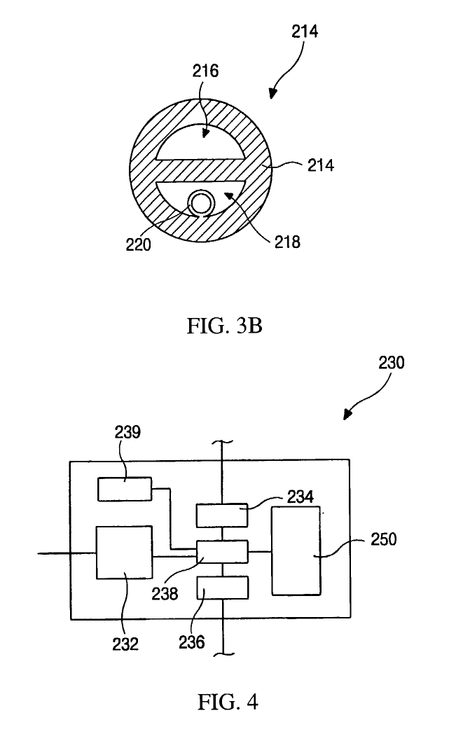

The apparatus 100 includes a sensing system 200, which is composed of a viewer port 210, a logical operator 230 and an image pickup device 240 of FIG. 3A. The viewer port 210 is showed in detail in FIGS. 3A and 3B. FIG. 3A is a cross-sectional view of magnifying the part “A” of FIG. 2 and FIG. 3B is a view of showing a viewer frame. The viewer port 210 passes through a side of the chamber 120, so that the interior of the chamber 120 is observed through the viewer port 210. The viewer port 210 has a window viewer 212, a viewer frame 214 and a bracket 220.

The viewer frame 214 is composed of has a first opening 216 and a second opening 218. The viewer frame 214 fixes the window viewer 212 on the chamber 120. The window viewer 212 is made of quartz because plastics or glass is damaged by high temperature on process and becomes as impurity. The bracket 220 is formed in the second opening 218 and contacts the viewer frame 214. The bracket 220 may be formed in the first opening 216. The viewer frame 214 has a circular shape and the first and second openings 216 and 218 are semicircular. The first and second openings 216 and 218 face each other. The image pickup device 240 connects the viewer port 210 to the logical operator 230.

A computer system desirably is used as the logical operator 230. The logical operator 230 is illustrated in FIG. 4. The logical operator 230 includes a first conversion unit 232 that changes image data into manageable data, a control unit 238 that analyzes the manageable data and decides whether the manageable data is wrong, second and third conversion units 234 and 236 that generate control signals to control the plasma generation source 150 and the bias source 160, respectively, a database 239 having data on normal operation and data on abnormal operation, and an indicating unit 250 that shows analysis results of the control unit 238 to an user. The control unit 238 is electrically connected to the first conversion unit 232, the second and third conversion units 234 and 236, the database 239 and the indicating unit 250. The first conversion unit 232 is connected to the image pickup device 240. The second conversion unit 234 is connected to the first power source 152 and the first impedance matching system 154 of the plasma generation source 150. The third conversion unit 236 is connected to the second power source 166 and the second impedance matching system 164 of the bias source 160.

The first, second and third conversion units 232, 234 and 236 may be hardware of an electric circuit, or software installed in the computer system when the computer system is used as the logical operator 230.

An operation of the apparatus according to the present invention will be illustrated in connection with the operation of the chamber 120 (of FIG. 2).

As shown in FIGS. 2 and 4, after a substrate 1 is loaded on a chuck 130 of a chamber 120 and the chamber 120 is closed, a source material and a reaction material are injected into the chamber 120 through an inlet 123 from a storage part 140. The source material and the reaction material are excited to become a plasma by a plasma generation source 150 of a first region 128a and a bias source 160 of a second region 128b, and used for etching a thin film of the substrate 1. In the present invention, these procedures are instantly detected by a sensing system 200. An image pickup device 240 senses a state of the second region 128b of the chamber 120 through a window viewer 212. The image pickup device 240 makes image data showing the state of the second region 128b and transmits the image data to a first conversion unit 232 of a logical operator 230. For example, the image data shows a substrate alignment state, normal and abnormal state of a process or a deformation state of the substrate according to a temperature. Next, the first conversion unit 232 transforms the image data to manageable data of a specific form and transmits the manageable data to a control unit 238. The control unit 238 analyzes the manageable data and decides whether the state of the second region 128b is normal or not. The control unit 238 may have reference data of a normal state and an abnormal state previously inputted to compare the reference data with the manageable data. Accordingly, the control unit 238 may include a data base 239 for saving the reference data. If the state of the second region 128b is decided to be normal, the control unit 238 does not generate any control signal and the process continues. However, if the second region 128b is decided to be abnormal, the control unit 238 may adjust the process in two ways.

First, if the abnormal state is the same type as the inputted reference data, the abnormal state will be easily overcome by adjusting an impedance value of a first impedance matching system 154 of the plasma generation source 150 and/or of a second impedance matching system 164 of the bias source 160. Accordingly, the control unit 238 transmits a signal including a calibrated impedance value to second and/or third conversion units 234 and/or 236. The second and/or third conversion units 234 and/or 236 transforms the signal to a control signal, and transmits the control signal to the first and/or second impedance matching systems 154 and/or 164.

Second, if the abnormal state is different from the inputted reference data, the abnormal state will not be overcome by adjusting the first and/or impedance matching systems 154 and/or 164. Accordingly, the control unit 238 transmits a off-data to turn off first and second power sources 152 and 166 to the second and third conversion units 234 and 236. The second and third conversion units 234 and 236 transform the off-data to an off-signal and transmit the off-signal to the first and second power sources 152 and 166. Thus, the process stops.

Here, when the abnormal state is sensed, the control unit 238 displays the abnormal state through an indicating unit 240. For example, the indicating unit 240 may be an image display device, a buzzer or a warning flare, or complex thereof. Accordingly, users can detect the abnormal state of the chamber 120 through the indicating unit 240 and take appropriate measures to the abnormal state. As a result, the process is well performed.

Consequently, in a manufacturing apparatus of a semiconductor device according to the present invention, a substrate alignment state, normal and abnormal state of a process or a deformation state of the substrate according to a temperature is instantly detected and a process is reliably performed because adequate measures are taken according to the detection. Especially, since a window viewer is made of quartz, a process in a chamber is not disturbed. Moreover, a window frame has first and second openings the process is respectively sensed by a bare eye and an image pickup device to fix the window viewer. Accordingly, the process is more accurately sensed. Furthermore, since a logical operator that analyzes, decides and displays a state of the chamber, and solve the problem is included, a process is smoothly performed to fabricate a more reliable device.

It will be apparent to those skilled in the art that various modifications and variations can be made in the fabrication and application of the present invention without departing from the spirit or scope of the invention. Thus, it is intended that the present invention cover the modifications and variations of this invention provided they come within the scope of the appended claims and their equivalents.

What is claimed is:

1. An apparatus of manufacturing a semiconductor device, comprising:
a chamber having a sidewall;
a window viewer of transparent material passing through the sidewall of the chamber;
a window frame fixing the window viewer in the sidewall, the window frame having at least one opening;
an image pickup device in the at least one opening, the image pickup device making image data showing a state of the chamber; and
a logical operator connected to the image pickup device, the logical operator deciding whether the state of the chamber is normal or not by analyzing the image data.

2. The apparatus according to claim 1, wherein the window viewer includes a quartz.

3. The apparatus according to claim 1, wherein the window frame includes a bracket in the at least one opening, the bracket fixing the image pickup device.

4. The apparatus according to claim 4, wherein the bracket has a cylinder shape.

5. The apparatus according to claim 4, wherein the bracket is substantially normal to the sidewall.

6. The apparatus according to claim 1, wherein the image pickup device includes one of a charge coupled device (CCD) camera, a personal computer camera, an optical fiber scope and a wide viewing lens.

7. The apparatus according to claim 1, wherein the logic operator comprises:
a first conversion unit transforming the image data into manageable data;
a control unit analyzing the manageable data; and
an indicating unit showing analysis results of the control unit.

8. The apparatus according to claim 7, wherein the control unit compares the manageable data with reference data previously inputted.

9. The apparatus according to claim 8, wherein the control unit includes a data base, the reference data being saved in the data base.

10. The apparatus according to claim 7, wherein the indicating unit includes an image display device, a buzzer or a warning flare.

11. The apparatus according to claim 7, wherein the chamber comprises:
a plate dividing an interior of the chamber into first and second regions;
a plasma generation source in the first region; and
a chuck in the second region, the chuck having a bias source therein.

12. The apparatus according to claim 10, wherein the logic operator further comprises:
a second conversion unit connected to the plasma generation source; and
a third conversion unit connected to the bias source.

13. The apparatus according to claim 11, wherein the second conversion unit transmits an off signal to the plasma generation source according to the analysis results.

14. The apparatus according to claim 11, wherein the third conversion unit transmits an off signal to the bias source according to the analysis results.
